(19) United States
(12) Patent Application Publication
(10) Pub. No.: US 2026/0231690 A1
(43) Pub. Date: Aug. 6, 2026

(54) QUANTUM DEVICE

(71) Applicant: NEC Corporation, Tokyo (JP)

(72) Inventor: Keisuke TAHARA, Tokyo (JP)

(73) Assignee: NEC Corporation, Tokyo (JP)

(21) Appl. No.: 19/445,795

(22) Filed: Jan. 12, 2026

(30) Foreign Application Priority Data
Feb. 3, 2025 (JP) 2025-016074

(51) Int. Cl. H10N 60/81

(52) U.S. Cl. CPC H10N 60/815

(57) ABSTRACT

A quantum device includes a quantum chip, an interposer on which the quantum chip is mounted, and a socket including a first movable pin including a first barrel having a first end in a first direction of an axial direction and a first plunger movable in the axial direction with respect to the first barrel, a first dielectric member, and an outer conductor located at an outer periphery of the first plunger with the first dielectric member interposed between the outer conductor and the first plunger and in contact with the interposer. The first plunger has a first distal portion protruding in the axial direction from the first end and in contact with the interposer. The first dielectric member covers the outer periphery of the first distal portion from the first end to the interposer.

This application is based upon and claims the benefit of priority from Japanese Patent Application No. 2025-016074, filed on February 3, 2025, the disclosure of which is incorporated herein in its entirety by reference.

### TECHNICAL FIELD

The present disclosure relates to a quantum device.

### BACKGROUND ART

As disclosed in JP 2022-2234 A, in a quantum device in which a quantum chip using superconductivity is mounted on an interposer by a flip chip (FC), a structure using a socket having a movable pin has been proposed.

For example, JP 2022-2234 A discloses a quantum device in which a socket is disposed facing an interposer on which a quantum chip is mounted, and a substrate is disposed on the other end face of the socket.

### SUMMARY

In the quantum device disclosed in JP 2022-2234 A, for example, the characteristic impedance of the connection portion when the socket and the interposer, and the socket and the substrate are electrically connected to each other may be difficult to match. Therefore, the electrical characteristics of the connection portion may be deteriorated.

An object of the present disclosure is to provide a quantum device that solves any of the problems described above.

A quantum device according to an aspect of the present disclosure includes a quantum chip, an interposer on which the quantum chip is mounted, and a socket including a first movable pin including a first barrel having a first end in a first direction of an axial direction and a first plunger movable in the axial direction with respect to the first barrel, a first dielectric member, and an outer conductor located at an outer periphery of the first plunger with the first dielectric member interposed between the outer conductor and the first plunger and in contact with the interposer, wherein the first plunger has a first distal portion that protrudes in the axial direction from the first end and is in contact with the interposer, and the first dielectric member covers an outer periphery of the first distal portion from the first end to the interposer.

According to the above aspect, the electrical characteristics of the connection portion can be improved.

### BRIEF DESCRIPTION OF THE DRAWINGS

Exemplary features and advantages of the present disclosure will become apparent from the following detailed description when taken with the accompanying drawings in which:

FIG. 1 is a side view of a quantum device according to the present disclosure;

FIG. 2 is a cross-sectional view of the quantum device according to the present disclosure;

FIG. 3 is a partial cross-sectional view of a first movable pin according to the present disclosure;

FIG. 4 is a cross-sectional view taken along line IV-IV of FIG. 1;

FIG. 5 is a cross-sectional view taken along line V-V of FIG. 1;

FIG. 6 is a cross-sectional view of a socket according to the first comparative example;

FIG. 7 is a partial cross-sectional view of a first movable pin according to a first modification of the present disclosure;

FIG. 8 is a cross-sectional view of a socket according to the second and third modifications of the present disclosure;

FIG. 9 is an enlarged view of a first end and a second end of FIG. 8;

FIG. 10 is an enlarged cross-sectional view of a first end and a second end of a socket according to the fourth and fifth modifications of the present disclosure;

FIG. 11 is a cross-sectional view of a quantum device according to the present disclosure;

FIG. 12 is an arrow view of the socket according to the present disclosure taken along arrow XII illustrated in FIG. 11;

FIG. 13 is a cross-sectional view of a socket according to the second comparative example;

FIG. 14 is a cross-sectional view of a first movable pin, an outer conductor, and a first dielectric member according to the fourth modification of the present disclosure;

FIG. 15 is a plan view of a first movable pin and a second movable pin according to the fifth modification of the present disclosure; and

FIG. 16 is a cross-sectional view of a socket according to the present disclosure.

### EXAMPLE EMBODIMENT

Hereinafter, each example embodiment will be described with reference to the drawings. In all the drawings, the same or related components are denoted by the same reference numerals, and the common description will be omitted.

### First Example Embodiment

Hereinafter, an example embodiment according to the present disclosure will be described with reference to the drawings.

### Configuration

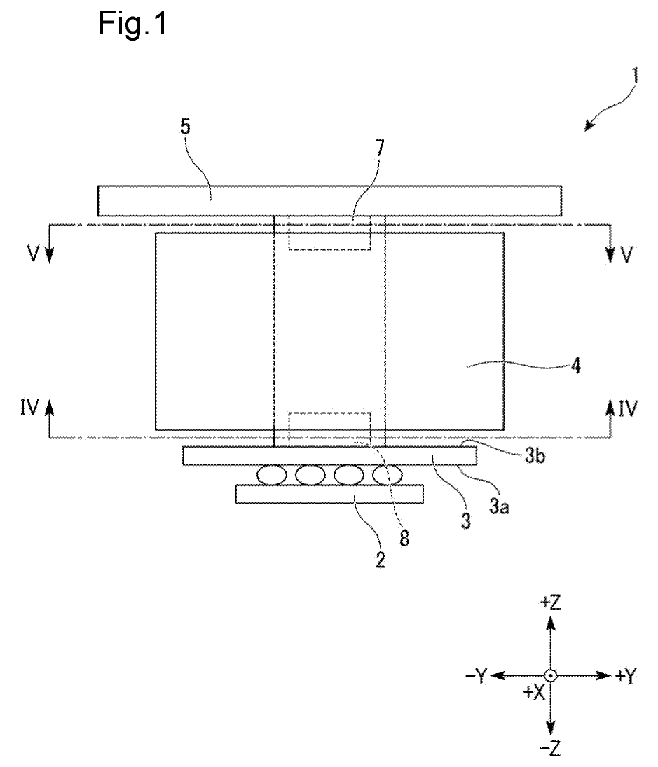

As illustrated in FIG. 1, a quantum device 1 according to the present example embodiment includes a quantum chip 2, an interposer 3, a socket 4, and a printed circuit board 5.

### Configurations of Quantum Chip and Interposer

The quantum chip 2 includes a superconducting material. The superconducting material includes, for example, a superconducting metal that functions as a superconductor at a cryogenic temperature. The quantum chip 2 is electrically connected to the interposer 3. The quantum chip 2 is mounted on a mounting face 3a of the interposer 3 in the -Z direction by flip-chip connection.

The socket 4 is installed on a facing face 3b of the interposer 3 in the +Z direction. The facing face 3b may be, for example, a plane facing in the +Z direction. The interposer 3 may be located, for example, between the quantum chip 2 and the socket 4. The interposer 3 may be provided, for example, to increase the number of terminals to the outside. The interposer 3 may include, for example, a plurality of wires that increases the pitch between the terminals of the quantum chip 2 from the face facing in the -Z direction toward the end face facing in the +Z direction.

### Configuration of Socket

The socket 4 is electrically connected to each of the interposer 3 and the printed circuit board 5.

The socket 4 is located between the interposer 3 and the printed circuit board 5.

The socket 4 relays the electrical connection between the interposer 3 and the printed circuit board 5.

One end face of the socket 4 facing in the -Z direction faces the interposer 3.

The other end face of the socket 4 facing in the +Z direction faces the printed circuit board 5.

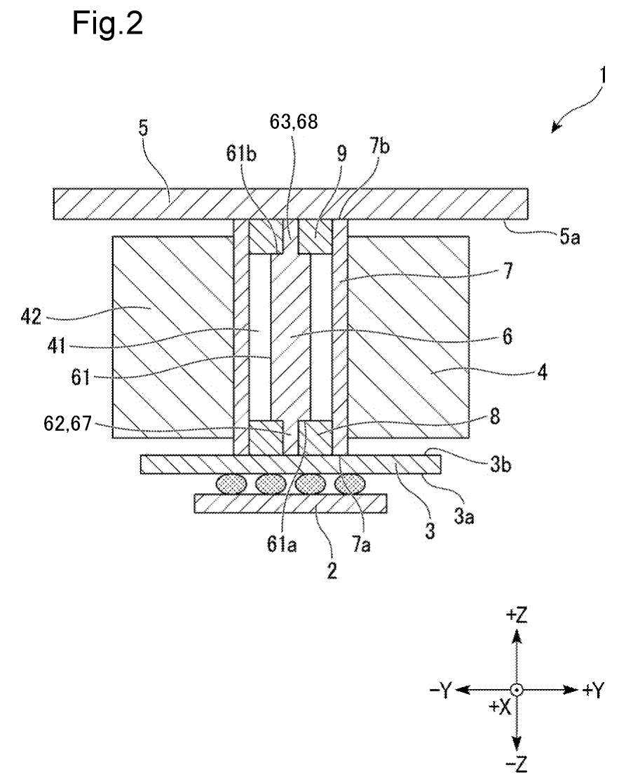

As illustrated in FIG. 2, the socket 4 includes a first movable pin 6, an outer conductor 7, a first dielectric member 8, a second dielectric member 9, a third dielectric member 41, and a housing 42. The socket 4 has a cylindrical coaxial structure with the first movable pin 6 as a central conductor (signal).

Hereinafter, a direction in which a first plunger to be described later moves with respect to a first barrel to be described later is referred to as a Z direction. One direction of the Z direction (direction from the interposer toward the socket) is referred to as a +Z direction.

The other direction of the Z direction (a direction opposite to the +Z direction) is referred to as a -Z direction.

The Z direction is an example of the axial direction. The -Z direction is an example of a first direction of the axial direction. The +Z direction is an example of a second direction of the axial direction.

A direction intersecting the Z direction is referred to as an X direction. One direction of the X direction is referred to as a +X direction. The other direction of the X direction (a direction opposite to the +X direction) is referred to as a -X direction.

For example, the X direction may be orthogonal to the Z direction.

A direction intersecting the Z direction and the X direction is referred to as a Y direction. One direction of the Y direction is referred to as a +Y direction. The other direction of the Y direction (a direction opposite to the +Y direction) is referred to as a -Y direction.

For example, the Y direction may be orthogonal to the Z direction and orthogonal to the X direction.

### Configuration of Movable Pin

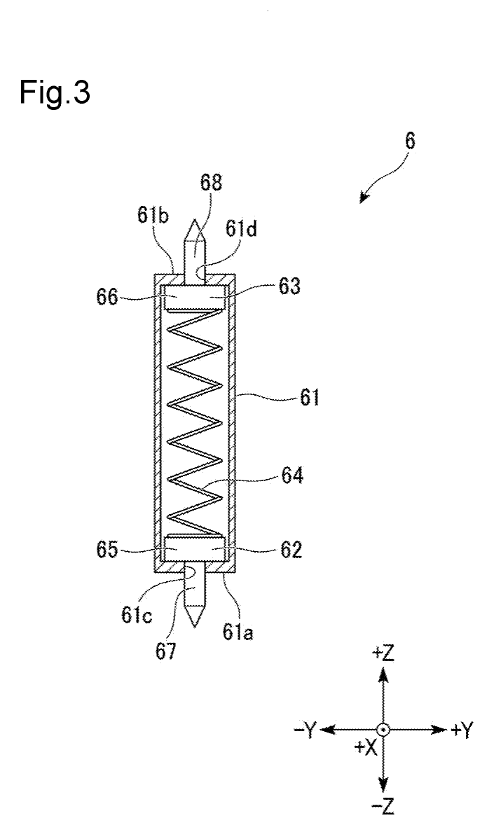

As illustrated in FIG. 3, the first movable pin 6 includes a first barrel 61, a first plunger 62, a second plunger 63, and a spring 64. The first movable pin 6 may be, for example, of a both-end movable type in which each of the first plunger 62 and the second plunger 63 is movable in the Z direction with respect to the first barrel 61. The first plunger 62 and the second plunger 63 are held at both ends of the first barrel 61 in the Z direction (longitudinal direction) via the spring 64.

The first barrel 61 has a cylindrical shape having a central axis extending in the Z direction. The first barrel 61 holds the first plunger 62 at a portion of the first barrel 61 in the -Z direction. The first barrel 61 holds the second plunger 63 at a portion of the first barrel 61 in the +Z direction.

The first barrel 61 has a first end 61a in the -Z direction and a second end 61b in the +Z direction.

The first barrel 61 has a first hole 61c and a second hole 61d.

The first hole 61c extends in the -Z direction from the hollow inside of the first barrel 61 toward the outside of the first barrel 61. The first hole 61c is opened in the -Z direction at the first end 61a.

The second hole 61d extends in the +Z direction from the hollow inside of the first barrel 61 toward the outside of the first barrel 61. The second hole 61d opens in the +Z direction at the second end 61b.

The first barrel 61 may be formed of, for example, a conductive metal material.

The first plunger 62 includes a first base portion 65 and a first distal portion 67. The first distal portion 67 extends from the first base portion 65 toward the -Z direction.

The first plunger 62 is movable in the Z direction with respect to the first barrel 61.

The first plunger 62 is accommodated in the first barrel 61 except for a portion of the first distal portion 67 (a portion protruding from the first end 61a).

The first plunger 62 and the first barrel 61 are in conductive contact with each other.

For example, the first plunger 62 may be disposed coaxially with the first barrel 61.

The first plunger 62 may be formed of, for example, a conductive metal material.

The first base portion 65 may have, for example, a disk shape having an outer peripheral diameter larger than the hole diameter of the first hole 61c.

The first distal portion 67 penetrates the first hole 61c from the first base portion 65 and protrudes in the -Z direction from the first end 61a. The first distal portion 67 is in contact with the interposer 3 in a state in which the first distal portion 67 moves in the -Z direction (see FIG. 2).

For example, the first distal portion 67 may be an integrally molded product with the first base portion 65.

The second plunger 63 includes a second base portion 66 and a second distal portion 68. The second distal portion 68 extends from the second base portion 66 toward the +Z direction.

For example, the second plunger 63 may be movable in the Z direction with respect to the first barrel 61.

The second plunger 63 is accommodated in the first barrel 61 except for a portion of the second distal portion 68 (a portion protruding from the second end 61b).

The second plunger 63 and the first barrel 61 are in conductive contact with each other.

The second plunger 63 may be disposed coaxially with the first barrel 61, for example.

The second plunger 63 may be formed of, for example, a conductive metal material.

The second base portion 66 may have, for example, a disk shape having an outer peripheral diameter larger than the hole diameter of the second hole 61d.

The second distal portion 68 penetrates the second hole 61d from the second base portion 66 and protrudes in the +Z direction from the second end 61b. The second distal portion 68 is in contact with the printed circuit board 5 in a state in which the second distal portion 68 moves in the +Z direction (see FIG. 2).

For example, the second distal portion 68 may be an integrally molded product with the second base portion 66.

The spring 64 extends in the Z direction. The spring 64 is entirely accommodated in the first barrel 61. A portion of the spring 64 in the -Z direction is in contact with a portion of the first plunger 62 in the +Z direction. A portion of the spring 64 in the +Z direction is in contact with a portion of the second plunger 63 in the -Z direction.

The spring 64 can bias the first plunger 62 and the second plunger 63 in the Z direction. The spring 64 can bias the first plunger 62 and the second plunger 63 in directions away from each other. The spring 64 may be, for example, a coil spring that extends in the Z direction and is stretchable in the Z direction.

Since the interposer 3 and the terminal (pad) of the printed circuit board 5 suppress the separation of the first plunger 62 and the second plunger 63 in the Z direction, the first plunger 62 and the second plunger 63 are biased by the spring 64 in such a way as to be away from each other in the Z direction. As a result, the first distal portion 67 and the second distal portion 68 protruding from the first barrel 61 are biased in such a way as to be elastically movable in the Z direction.

### Configuration of Outer Conductor

As illustrated in FIGS. 2, 4, and 5, the outer conductor 7 has a cylindrical shape having a central axis extending in the Z direction. The first movable pin 6 is accommodated in the hollow portion of the outer conductor 7. The outer conductor 7 and the first barrel 61 are coaxially disposed.

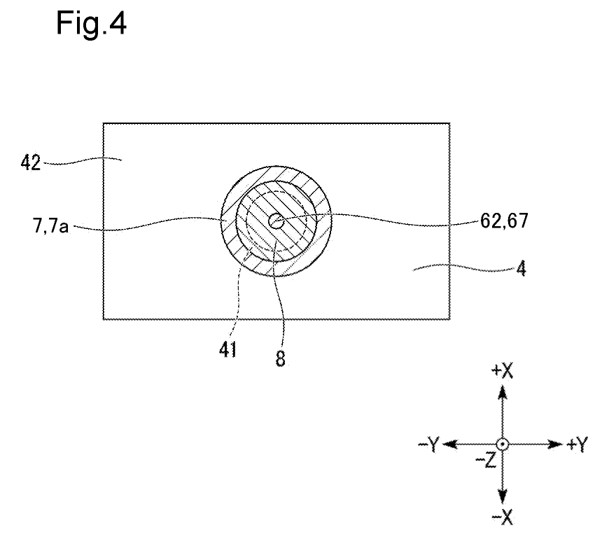

As illustrated in FIGS. 2 and 4, the outer conductor 7 is located at the outer periphery of the first distal portion 67 of the first plunger 62 with the first dielectric member 8 interposed between the outer conductor 7 and the first plunger 62. The outer conductor 7 is in contact with the interposer 3 in the -Z direction. The outer conductor 7 has a first face 7a in contact with the facing face 3b along the XY plane of the interposer 3 in the -Z direction. The first face 7a may be, for example, an annular plane that is along the XY plane and faces in the -Z direction.

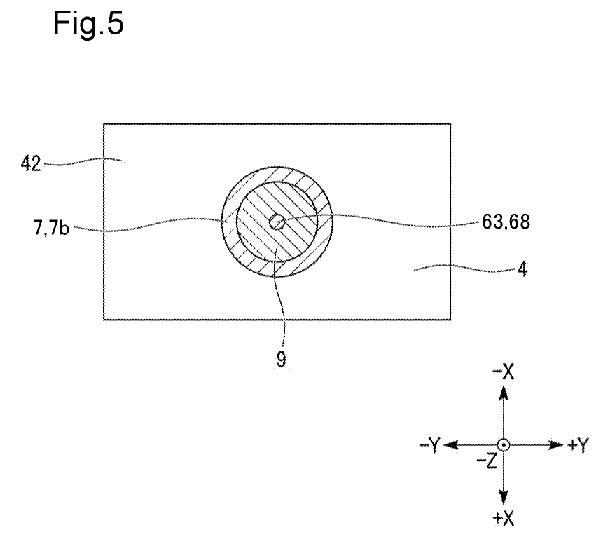

As illustrated in FIGS. 2 and 5, the outer conductor 7 is located at the outer periphery of the second distal portion 68 of the second plunger 63 with the second dielectric member 9 interposed between the outer conductor 7 and the second plunger 63. The outer conductor 7 is in contact with the interposer 3 in the -Z direction. The outer conductor 7 is in contact with the printed circuit board 5 in the +Z direction. The outer conductor 7 has a second face 7b in contact with a facing face 5a of the printed circuit board 5 described later in the +Z direction. The second face 7b may be, for example, an annular plane that is along the XY plane and faces in the +Z direction.

The outer conductor 7 may be a ground (GND) conductor (grounded conductor).

The outer conductor 7 may be formed of, for example, a conductive metal material.

### Configuration of First Dielectric Member

As illustrated in FIGS. 2 and 4, the first dielectric member 8 covers the outer periphery of the first distal portion 67 from the first end 61a of the first barrel 61 to the interposer 3. The first dielectric member 8 has a cylindrical shape or a disk shape having a central axis extending in the Z direction. The first dielectric member 8 is disposed coaxially with the outer conductor 7 and the first distal portion 67.

The first dielectric member 8 may be formed of, for example, an electrically insulatable resin material.

For example, the first dielectric member 8 may have a thickness equal to the distance between the first end 61a of the first barrel 61 and the interposer 3 in the Z direction. That is, the thickness of the first dielectric member 8 in the Z direction may be, for example, substantially the same as the length of a portion of the first distal portion 67, the portion protruding from the first end 61a. On the other hand, the length of the outer conductor 7 further extending in the -Z direction with respect to the position of the first end 61a of the first barrel 61 in the Z direction may be, for example, substantially the same as the length of a portion of the first distal portion 67, the portion protruding from the first end 61a. With these configurations, the characteristic impedance to the distal portion of the first plunger 62 is adjusted.

### Configuration of Second Dielectric Member

As illustrated in FIGS. 2 and 5, the second dielectric member 9 covers the outer periphery of the second distal portion 68 from the second end 61b of the first barrel 61 to the printed circuit board 5. The second dielectric member 9 has a cylindrical shape or a disk shape having a central axis extending in the Z direction. The second dielectric member 9 is disposed coaxially with the outer conductor 7 and the second distal portion 68.

The first dielectric member 8 may be formed of, for example, an electrically insulatable resin material.

For example, the second dielectric member 9 may have a thickness equal to the distance between the second end 61b of the first barrel 61 and the printed circuit board 5 in the Z direction. That is, the thickness of the second dielectric member 9 in the Z direction may be, for example, substantially the same as the length of the portion of the second distal portion 68, the portion protruding from the second end 61b. On the other hand, the length of the outer conductor 7 further extending in the +Z direction with respect to the position of the second end 61b of the first barrel 61 in the Z direction may be, for example, substantially the same as the length of a portion of the second distal portion 68, the portion protruding from the second end 61b. With these configurations, the characteristic impedance to the distal portion of the second plunger 63 is adjusted.

### Configuration of Third Dielectric Member

As illustrated in FIGS. 2 and 4, the third dielectric member 41 covers the outer periphery of the first barrel 61 from the first end 61a to the second end 61b of the first barrel 61. The third dielectric member 41 has a cylindrical shape having a central axis extending in the Z direction. The third dielectric member 41 is disposed coaxially with the outer conductor 7 and the first barrel 61.

The third dielectric member 41 may be formed of, for example, an electrically insulatable resin material.

A portion of the third dielectric member 41 in the -Z direction may be, for example, in contact with a portion of the first dielectric member 8 in the +Z direction, or may be slightly away from a portion of the first dielectric member 8 in the +Z direction to the extent that the impedance characteristics are not affected. A portion of the third dielectric member 41 in the +Z direction may be in contact with, for example, a portion of the second dielectric member 9 in the -Z direction, or may be slightly away from a portion of the second dielectric member 9 in the -Z direction to the extent that impedance characteristics are not affected.

### Configuration of Housing

The housing 42 supports the outer conductor 7 from the outer periphery of the outer conductor 7. The housing 42 covers the outer periphery of the outer conductor 7. The outer conductor 7 penetrates the housing 42 in the Z direction. In the -Z direction, the housing 42 may be away from the facing face 3b of the interposer 3. In the +Z direction, the housing 42 may be away from a facing face 5a (described later) of the printed circuit board 5.

The housing 42 may be formed of, for example, an electrically insulatable resin material.

### Configuration of Printed Circuit Board

The printed circuit board 5 is electrically connected to the quantum chip 2 via the interposer 3 and the socket 4. The printed circuit board 5 may be connected to the quantum chip 2 via the interposer 3 and the socket 4 in such a way as to be able to transmit an electromagnetic wave such as a microwave, for example. The printed circuit board 5 is located further in the +Z direction than the socket 4. The printed circuit board 5 has a facing face 5a along the XY plane in the -Z direction. The facing face 5a is in contact with the second face 7b of the outer conductor 7.

### Operation

In the quantum device 1, electric signals are transmitted and received between the printed circuit board 5 and the quantum chip 2 via the interposer 3 and the socket 4. For example, electromagnetic waves such as microwaves may be transmitted and received between the printed circuit board 5 and the quantum chip 2 via the interposer 3 and the socket 4. At this time, the electromagnetic wave is transmitted through a transmission path formed by the first movable pin 6, the outer conductor 7, the first dielectric member 8, the second dielectric member 9, and the third dielectric member 41 and extending in the Z direction.

### Operation and Effect

According to the quantum device 1 of the present example embodiment, the first dielectric member 8 covers the outer periphery of the first distal portion 67 from the first end 61a (of the first barrel 61) to the interposer 3.

With this configuration, the characteristic impedance from the first end 61a to the portion where the first distal portion 67 is in contact with the interposer 3 can be adjusted by the first dielectric member 8.

Therefore, the characteristic impedance of the connection portion of the interposer 3 and the socket 4 can be matched.

Therefore, the electrical characteristics of the connection portion can be improved.

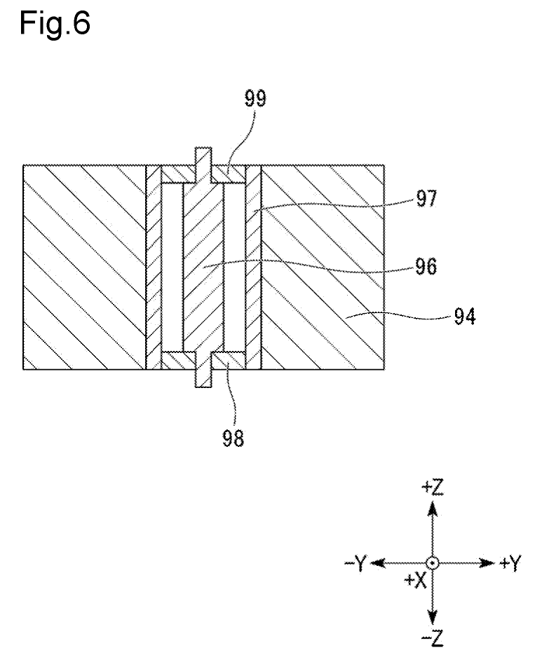

As the first comparative example, as illustrated in FIG. 6, in a case where a cylindrical coaxial structure including a first movable pin 96 and an outer conductor 97 is formed in a socket 94, it is assumed that the plunger portion of the first movable pin 96 protrudes from the surfaces of the dielectric members 98 and 99. With such a configuration, the dielectric members 98 and 99 are covered only up to the middle of the plunger portion. Therefore, the characteristic impedance is not adjusted at a portion where the dielectric members 98 and 99 are not covered.

Therefore, the characteristic impedance of the connection portion when the socket 94 and the interposer 3, and the socket 94 and the printed circuit board 5 are electrically connected to each other is not matched.

In contrast to the first comparative example, in the present example embodiment, as described above, the first dielectric member 8 covers the outer periphery of the first distal portion 67 from the first end 61a to the interposer 3. Therefore, the characteristic impedance of the connection portion of the interposer 3 and the socket 4 can be matched.

According to the quantum device 1 of the present example embodiment, the second dielectric member 9 covers the outer periphery of the second distal portion 68 from the second end 61b (of the first barrel 61) to the printed circuit board 5.

With this configuration, the characteristic impedance from the second end 61b to the portion where the second distal portion 68 is in contact with the printed circuit board 5 can be adjusted by the second dielectric member 9.

Thus, the characteristic impedance of the connection portion of the socket 4 and the printed circuit board 5 can be matched.

Therefore, the electrical characteristics of the connection portion can be improved.

For example, as compared with the first comparative example, in the present example embodiment, as described above, the second dielectric member 9 covers the outer periphery of the second distal portion 68 from the second end 61b to the printed circuit board 5. Therefore, the characteristic impedance of the connection portion of the printed circuit board 5 and the socket 4 can be matched.

According to the quantum device 1 of the present example embodiment, the first dielectric member 8 has a thickness equal to the distance between the first end 61a (of the first barrel 61) and the interposer 3.

With this configuration, the gap between the first end 61a and the interposer 3 can be filled with the first dielectric member 8.

Therefore, it is easy to make the characteristic impedance of the transmission path between the first barrel 61 and the interposer 3 constant.

Therefore, the electrical characteristics of the connection portion can be improved.

According to the quantum device 1 of the present example embodiment, the second dielectric member 9 has a thickness equal to the distance between the second end 61b (of the first barrel 61) and the printed circuit board 5.

With this configuration, the gap between the second end 61b and the printed circuit board 5 can be filled with the second dielectric member 9.

Therefore, it is easy to make the characteristic impedance of the transmission path between the first barrel 61 and the printed circuit board 5 constant.

Therefore, the electrical characteristics of the connection portion can be improved.

According to the quantum device 1 of the present example embodiment, the socket 4 has a cylindrical coaxial structure with the first movable pin 6 as a central conductor.

With this configuration, electromagnetic waves such as microwaves can be easily transmitted between the socket 4 and the interposer 3.

Electromagnetic waves such as microwaves can be easily transmitted between the socket 4 and the printed circuit board 5.

According to the quantum device 1 of the present example embodiment, the outer conductor 7 has a plane in contact with the interposer 3 in the -Z direction.

With this configuration, connection stability between the interposer 3 and the outer conductor 7 can be improved.

According to the quantum device 1 of the present example embodiment, the outer conductor 7 has a plane in contact with the printed circuit board 5 in the +Z direction.

With this configuration, connection stability between printed circuit board 5 and outer conductor 7 can be improved.

### First Modification

The above example embodiment shows an example in which the first movable pin 6 is of a both-end movable type in such a way that each of the first plunger 62 and the second plunger 63 is movable in the Z direction with respect to the first barrel 61. However, the second plunger may be configured in any manner as long as the first distal portion 67 and the second distal portion 68 protruding from the first barrel 61 are biased in such a way as to be elastically movable in the Z direction.

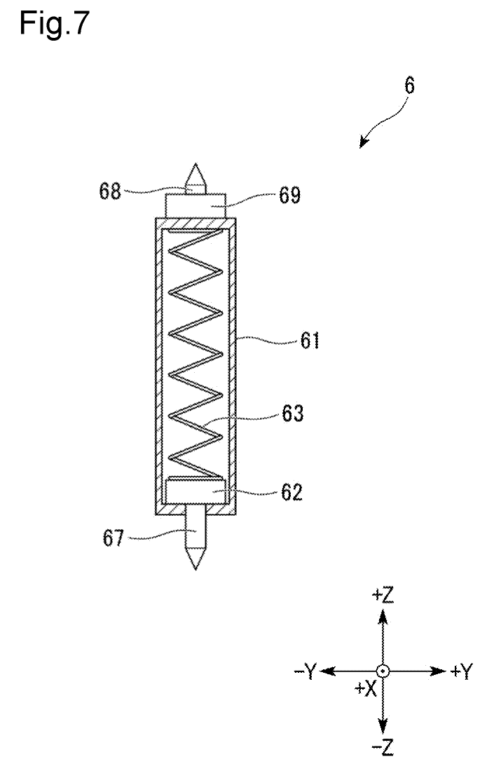

As illustrated in FIG. 7, as the first modification, the first movable pin 6 may include a second plunger 69 fixed to the first barrel 61. That is, the first movable pin 6 may be of a one-end movable type in such a way that only the first plunger 62 out of the first plunger 62 and the second plunger 69 is movable in the Z direction with respect to the first barrel 61.

Also in such the first modification, the first distal portion 67 and the second distal portion 68 protruding from the first barrel 61 are biased in such a way as to be elastically movable in the Z direction.

### Second and Third Modifications

The above example embodiment illustrates an example in which the first face 7a is an annular plane facing in the -Z direction. However, the first face 7a may be configured in any manner as long as the first face 7a is in contact with the facing face 3b of the interposer 3.

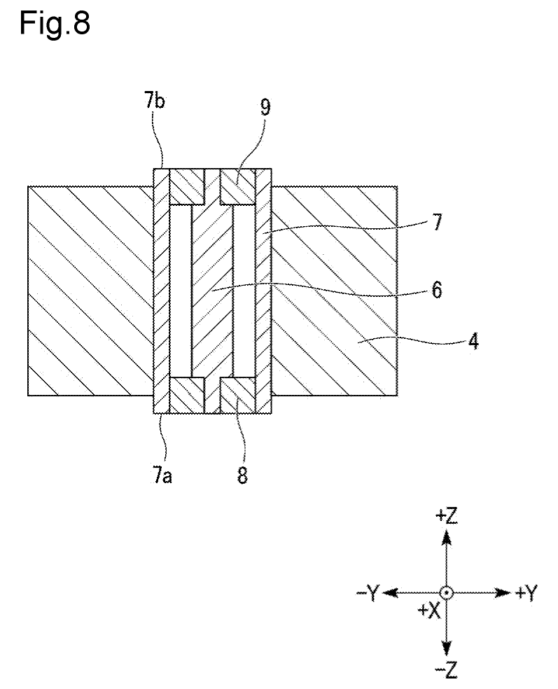

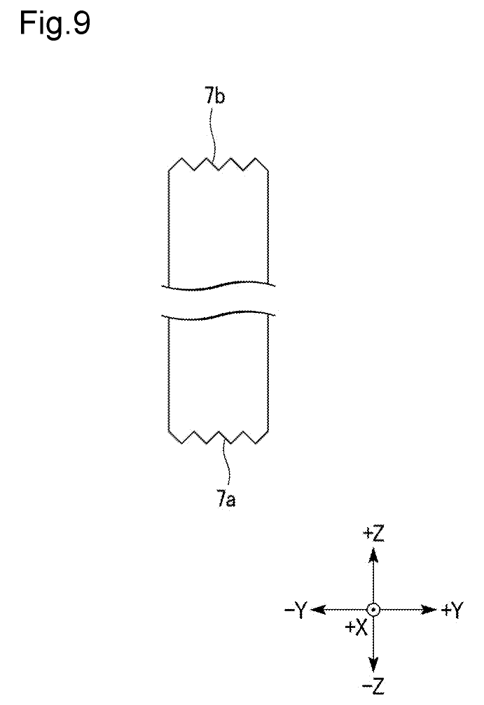

As illustrated in FIGS. 8 and 9, as the second modification, the first face 7a may have a plurality of protrusions. The first face 7a may have, for example, a multi-point crown shape as a shape having a plurality of protrusions.

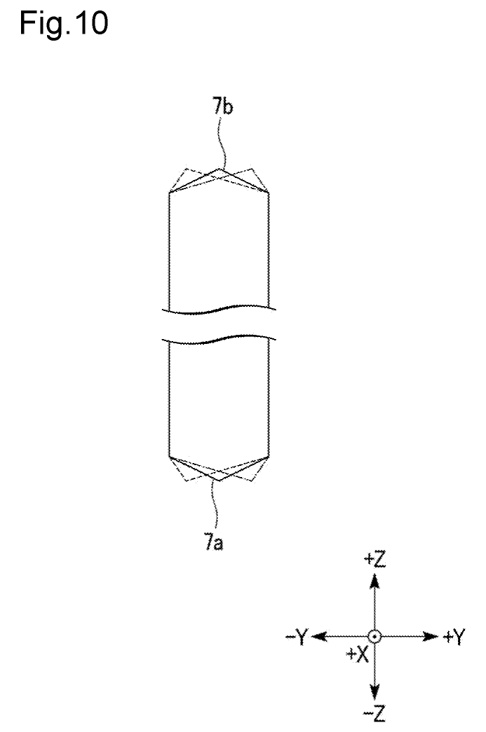

Furthermore, as illustrated in FIG. 10, as the third modification, the first face 7a may have only one protrusion. At this time, the position of the protrusion on the first face 7a may be at a position equidistant from the inner peripheral face and the outer peripheral face of the outer conductor 7 as indicated by a solid line in FIG. 10. The position of the protrusion on the first face 7a may be a position shifted in the Y direction from a position equidistant from the inner peripheral face and the outer peripheral face of the outer conductor 7 as indicated by a broken line or a dotted line in FIG. 10.

Even in the second and third modifications, the connection stability between the interposer 3 and the outer conductor 7 can be improved.

### Fourth and Fifth Modifications

The above example embodiment illustrates an example in which the second face 7b is an annular plane facing in the +Z direction. However, the second face 7b may be configured in any manner as long as the second face 7b is in contact with facing face 5a of the printed circuit board 5.

As illustrated in FIGS. 8 and 9, as the fourth modification, the second face 7b may have a plurality of protrusions. The second face 7b may have, for example, a multi-point crown shape as a shape having a plurality of protrusions.

Furthermore, as illustrated in FIG. 10, as the fifth modification, the second face 7b may have only one protrusion. At this time, the position of the protrusion on the second face 7b may be at a position equidistant from the inner peripheral face and the outer peripheral face of the outer conductor 7 as indicated by a solid line in FIG. 10. The position of the protrusion on the second face 7b may be a position shifted in the Y direction from a position equidistant from the inner peripheral face and the outer peripheral face of the outer conductor 7 as indicated by a broken line or a dotted line in FIG. 10.

Even in the fourth and fifth modifications, the connection stability between the printed circuit board 5 and the outer conductor 7 can be improved.

### Second Example Embodiment

Hereinafter, an example embodiment according to the present disclosure will be described with reference to the drawings. Note that the configuration of a quantum device 101 other than that described below is the same as the configuration of the quantum device 1.

### Configuration

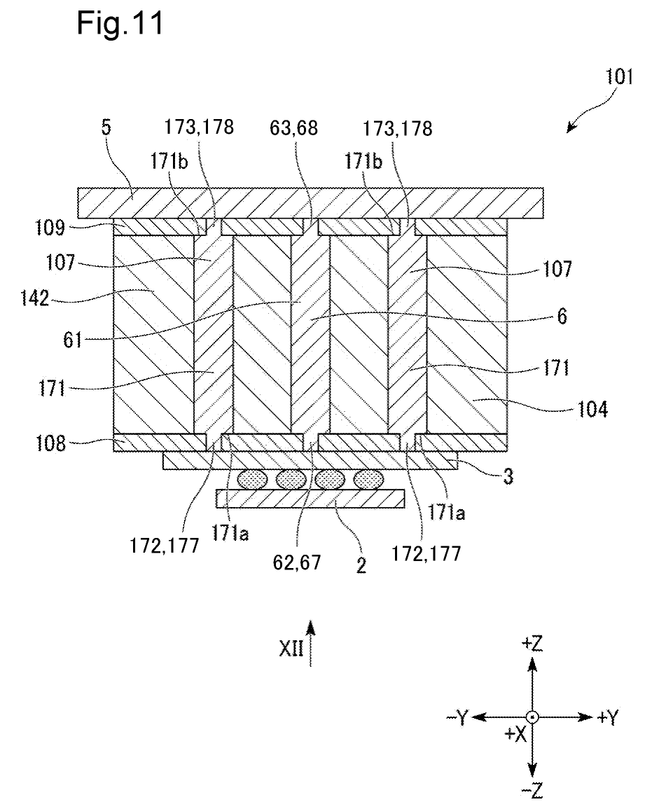

As illustrated in FIG. 11, the quantum device 101 according to the present example embodiment includes a quantum chip 2, an interposer 3, a socket 104, and a printed circuit board 5.

### Configuration of Socket

The socket 104 is electrically connected to each of the interposer 3 and the printed circuit board 5.

The socket 104 is located between the interposer 3 and the printed circuit board 5.

The socket 104 relays the electrical connection between the interposer 3 and the printed circuit board 5.

One end face of the socket 104 facing in the -Z direction faces the interposer 3.

The other end face of the socket 104 facing in the +Z direction faces the printed circuit board 5.

Socket 104 includes a first movable pin 6, a plurality of second movable pins 107 (outer conductors), a first dielectric member 108, a second dielectric member 109, and a housing 142.

### Configuration of Outer Conductor

Each of the plurality of second movable pins 107 includes a second barrel 171, a third plunger 172, and a fourth plunger 173.

The second movable pin 107 may further include, for example, a spring similar to that of the first movable pin 6 in the second barrel 171.

As in the first movable pin 6, the second movable pin 107 may be of a both-end movable type movable in the Z direction. That is, each of the third plunger 172 and the fourth plunger 173 may be movable in the Z direction with respect to the second barrel 171.

As in the first plunger 62 and the second plunger 63, the third plunger 172 and the fourth plunger 173 may be held at both ends of the second barrel 171 in the Z direction (longitudinal direction) via springs.

The second movable pin 107 may be a GND conductor (grounded conductor).

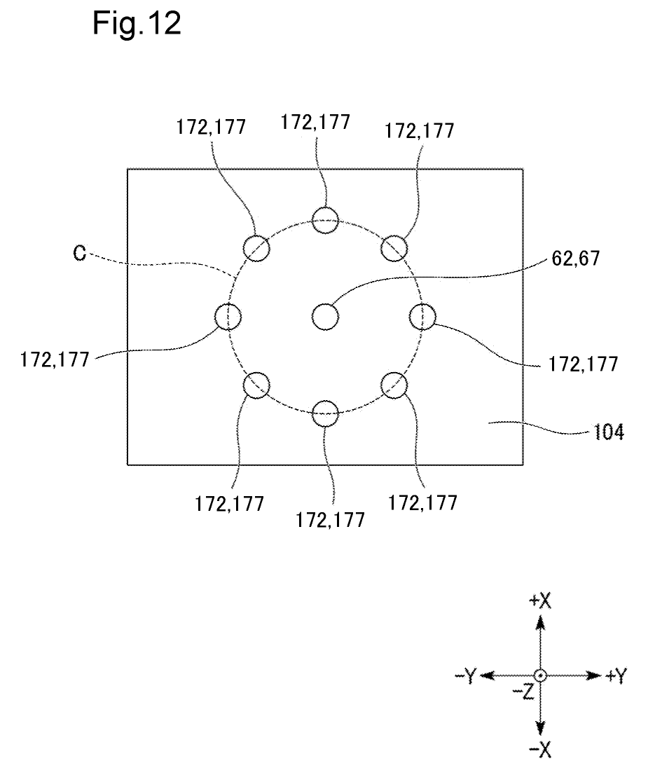

As illustrated in FIG. 12, the plurality of second movable pins 107 surround the outer periphery of the first movable pin 6. The plurality of second movable pins 107 is disposed on a circumference C centered on the first movable pin.

The second barrel 171 has a cylindrical shape having a central axis extending in the Z direction.

As illustrated in FIG. 11, the second barrel 171 holds the third plunger 172 in the -Z direction of the second barrel 171. The second barrel 171 holds the fourth plunger 173 in the +Z direction of the second barrel 171. The second barrel 171 has a third end 171a in the -Z direction and a fourth end 171b in the +Z direction.

The second barrel 171 may be formed of, for example, a conductive metal material.

The third plunger 172 has a third distal portion 177 extending in the -Z direction. The third distal portion 177 protrudes in the -Z direction from the third end 171a. The third plunger 172 is movable in the Z direction with respect to the second barrel 171. The third plunger 172 is accommodated in the second barrel 171 except for a portion of the third distal portion 177 (a portion protruding from the third end 171a). The third distal portion 177 is in contact with the interposer 3 in a state in which the third distal portion 177 moves in the -Z direction. The third plunger 172 and the second barrel 171 are in conductive contact with each other. The third plunger 172 may be disposed coaxially with the second barrel 171, for example.

The third plunger 172 may be formed of, for example, a conductive metal material.

The fourth plunger 173 has a fourth distal portion 178 extending in the +Z direction. The fourth distal portion 178 protrudes in the +Z direction from the fourth end 171b. For example, the fourth plunger 173 may be movable in the Z direction with respect to the second barrel 171. The fourth plunger 173 is accommodated in the second barrel 171 except for a portion of the fourth distal portion 178 (a portion protruding from the fourth end 171b). The fourth distal portion 178 is in contact with the printed circuit board 5 in a state in which the fourth distal portion 178 moves in the +Z direction. The fourth plunger 173 and the second barrel 171 are in conductive contact with each other. The fourth plunger 173 may be disposed coaxially with the second barrel 171, for example.

The fourth plunger 173 may be formed of, for example, a conductive metal material.

### Configuration of First Dielectric Member

The first dielectric member 108 covers the outer periphery of the first distal portion 67 from the first end 61a of the first barrel 61 to the interposer 3. The first dielectric member 108 has a plate shape having a plate thickness in the Z direction and extending along the XY plane.

Further, the first dielectric member 108 covers the outer periphery of each third distal portion 177 from the third end 171a of the second barrel 171 to the interposer 3.

The first dielectric member 108 may be formed of, for example, an electrically insulatable resin material.

For example, the first dielectric member 108 may have a thickness equal to the distance between the first end 61a of the first barrel 61 and the interposer 3 in the Z direction. That is, the thickness of the first dielectric member 108 in the Z direction may be, for example, substantially the same as the length of a portion of the first distal portion 67, the portion protruding from the first end 61a.

For example, the first dielectric member 108 may have a thickness equal to the distance between the third end 171a of the second barrel 171 and the interposer 3 in the Z direction. That is, the thickness of the first dielectric member 108 in the Z direction may be, for example, substantially the same as the length of a portion of the third distal portion 177, the portion protruding from the third end 171a.

The characteristic impedance to the distal portion of the first plunger 62 is adjusted by the configuration of the first dielectric member 108.

### Configuration of Second Dielectric Member

The second dielectric member 109 covers the outer periphery of the second distal portion 68 from the second end 61b of the first barrel 61 to the printed circuit board 5. The second dielectric member 109 has a plate shape having a plate thickness in the Z direction and extending along the XY plane.

Further, the second dielectric member 109 covers the outer periphery of each of the fourth distal portion 178 from the fourth end 171b of the second barrel 171 to the printed circuit board 5.

The second dielectric member 109 may be formed of, for example, an electrically insulatable resin material.

For example, the second dielectric member 109 may have a thickness equal to the distance between the second end 61b of the first barrel 61 and the printed circuit board 5 in the Z direction. That is, the thickness of the second dielectric member 109 in the Z direction may be, for example, substantially the same as the length of a portion of the second distal portion 68, the portion protruding from the second end 61b.

For example, the second dielectric member 109 may have a thickness equal to the distance between the fourth end 171b of the second barrel 171 and the printed circuit board 5 in the Z direction. That is, the thickness of the second dielectric member 109 in the Z direction may be, for example, substantially the same as the length of a portion of the fourth distal portion 178, the portion protruding from the fourth end 171b.

The characteristic impedance to the distal portion of the second plunger 63 is adjusted by the configuration of the second dielectric member 109.

### Configuration of Housing

The housing 142 integrally supports the first movable pin 6, the plurality of second movable pins 107, the first dielectric member 108, and the second dielectric member 109. The housing 142 covers the outer periphery of the first movable pin 6 and the outer periphery of the second movable pin 107. The first movable pin 6 penetrates the housing 142 in the Z direction. The second movable pin 107 penetrates the housing 142 in the Z direction.

In the -Z direction, the housing 142 may face the interposer 3 via the first dielectric member 108. A portion of the housing 142 in the -Z direction may be in surface contact with the interposer 3, for example.

In the +Z direction, the housing 142 may face the printed circuit board 5 via the second dielectric member 109. A portion of the housing 142 in the +Z direction may be in surface contact with the printed circuit board 5, for example.

The housing 142 may be formed of, for example, an electrically insulatable resin material.

### Configuration of Printed Circuit Board

The printed circuit board 5 is electrically connected to the quantum chip 2 via the interposer 3 and the socket 104. The printed circuit board 5 may be connected to the quantum chip 2 via the interposer 3 and the socket 104 in such a way as to be able to transmit an electromagnetic wave such as a microwave, for example. The printed circuit board 5 is located further in the +Z direction than the socket 104.

### Operation

In the quantum device 101, electric signals are transmitted and received between the printed circuit board 5 and the quantum chip 2 via the interposer 3 and the socket 104. For example, electromagnetic waves such as microwaves may be transmitted and received between the printed circuit board 5 and the quantum chip 2 via the interposer 3 and the socket 104. At this time, the electromagnetic wave is transmitted through a transmission path formed by the first movable pin 6, the plurality of second movable pins 107, the first dielectric member 108, and the second dielectric member 109 and extending in the Z direction.

### Operation and Effect

According to the quantum device 101 of the present example embodiment, the first dielectric member 108 covers the outer periphery of the first distal portion 67 from the first end 61a (of the first barrel 61) to the interposer 3.

With this configuration, the characteristic impedance from the first end 61a to the portion where the first distal portion 67 is in contact with the interposer 3 can be adjusted by the first dielectric member 108.

As a result, the characteristic impedance of the connection portion of the interposer 3 and the socket 104 can be matched.

Therefore, the electrical characteristics of the connection portion can be improved.

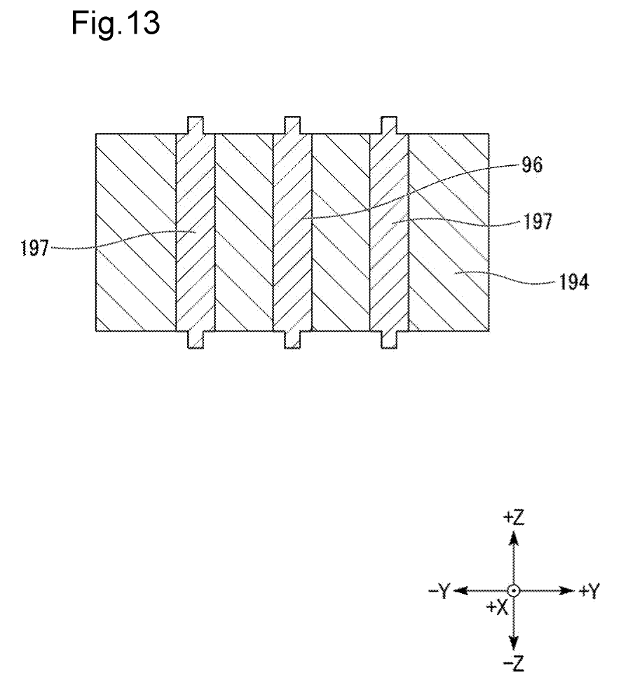

As the second comparative example, as illustrated in FIG. 13, in a case where a socket 194 includes the first movable pin 96 and the plurality of second movable pins 197, the plunger portion of the first movable pin 96 protrudes without being covered with the first dielectric member 108 and the second dielectric member 109. With such a configuration, the characteristic impedance is not adjusted in the plunger portion of the first movable pin 96. Therefore, the characteristic impedance of the connection portion when the socket 194 and the interposer 3, and the socket 194 and the printed circuit board 5 are electrically connected to each other is not matched.

In contrast to the second comparative example, in the present example embodiment, as described above, the first dielectric member 108 covers the outer periphery of the first distal portion 67 (surrounded by the plurality of third distal portions 177) from the first end 61a to the interposer 3. Therefore, the characteristic impedance of the connection portion of the interposer 3 and the socket 104 can be matched.

According to the quantum device 101 of the present example embodiment, the second dielectric member 109 covers the outer periphery of the second distal portion 68 from the second end 61b (of the first barrel 61) to the printed circuit board 5.

With this configuration, the characteristic impedance from the second end 61b to the portion where the second distal portion 68 is in contact with the printed circuit board 5 can be adjusted by the second dielectric member 109.

Thus, the characteristic impedance of the connection portion of the socket 104 and the printed circuit board 5 can be matched.

Therefore, the electrical characteristics of the connection portion can be improved.

For example, in contrast to the second comparative example, in the present example embodiment, as described above, the second dielectric member 109 covers the outer periphery of the second distal portion 68 (surrounded by the plurality of fourth distal portions 178) from the second end 61b to the printed circuit board 5. Therefore, the characteristic impedance of the connection portion of the printed circuit board 5 and the socket 104 can be matched.

According to the quantum device 101 of the present example embodiment, the first dielectric member 108 has a thickness equal to the distance between the first end 61a (of the first barrel 61) and the interposer 3.

With this configuration, the gap between the first end 61a and the interposer 3 can be filled with the first dielectric member 108.

Therefore, it is easy to make the characteristic impedance of the transmission path between the first barrel 61 and the interposer 3 constant.

Therefore, the electrical characteristics of the connection portion can be improved.

According to the quantum device 101 of the present example embodiment, the plurality of second movable pins 107 surrounds the first movable pin 6.

With this configuration, electromagnetic waves such as microwaves can be easily transmitted between the socket 104 and the interposer 3.

Electromagnetic waves such as microwaves can be easily transmitted between the socket 104 and the printed circuit board 5.

According to the quantum device 101 of the present example embodiment, the plurality of second movable pins 107 is disposed on the circumference centered on the first movable pin 6.

With this configuration, electromagnetic waves such as microwaves can be more easily transmitted between the socket 104 and the interposer 3.

Electromagnetic waves such as microwaves can be more easily transmitted between the socket 104 and the printed circuit board 5.

### Other Modifications

The transmission structure in the socket of each of the above example embodiments may be integrated.

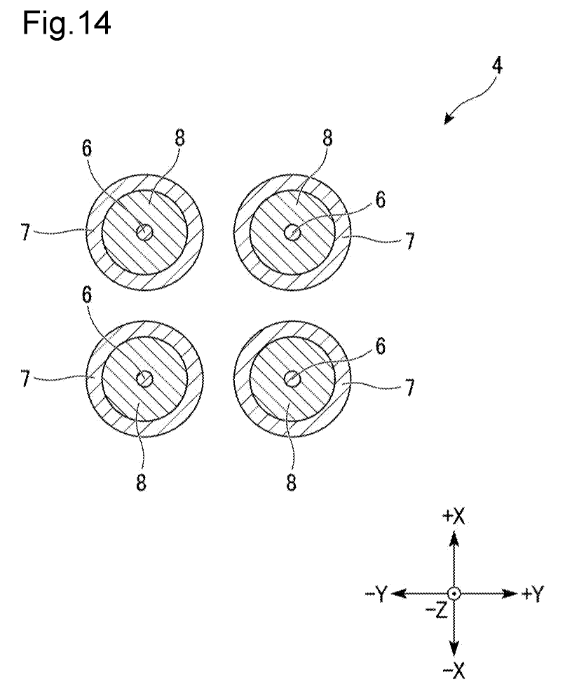

As the fourth modification, as illustrated in FIG. 14, the cylindrical coaxial structure may be integrated in the socket 4.

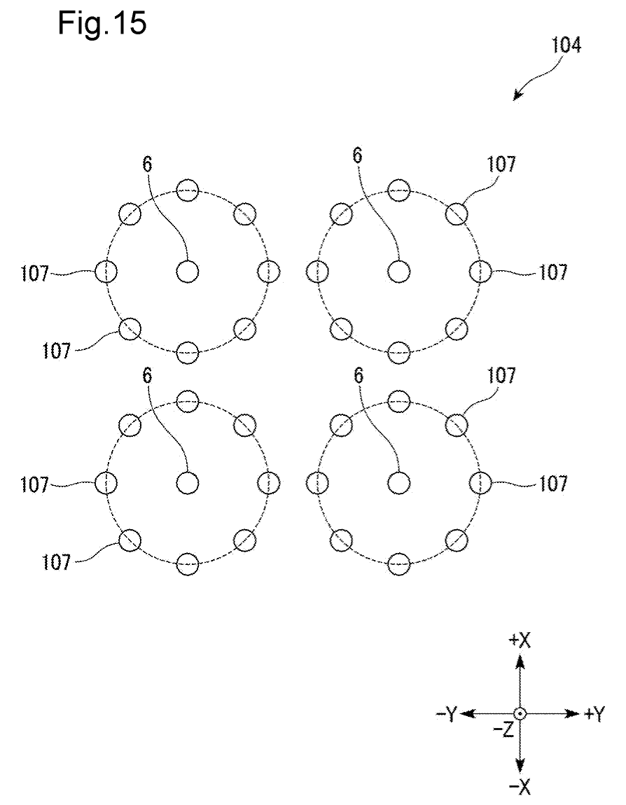

As the fifth modification, as illustrated in FIG. 15, in the socket 104, a set of the first movable pin 6 and the plurality of second movable pins 107 may be integrated.

However, since the socket 4 of the fourth modification does not use the movable pin for GND (the plurality of second movable pins 107) unlike the socket 104 of the fifth modification, space saving (miniaturization) can be achieved, and high integration can be achieved.

### Third Example Embodiment

Hereinafter, an example embodiment according to the present disclosure will be described with reference to the drawings.

### Configuration

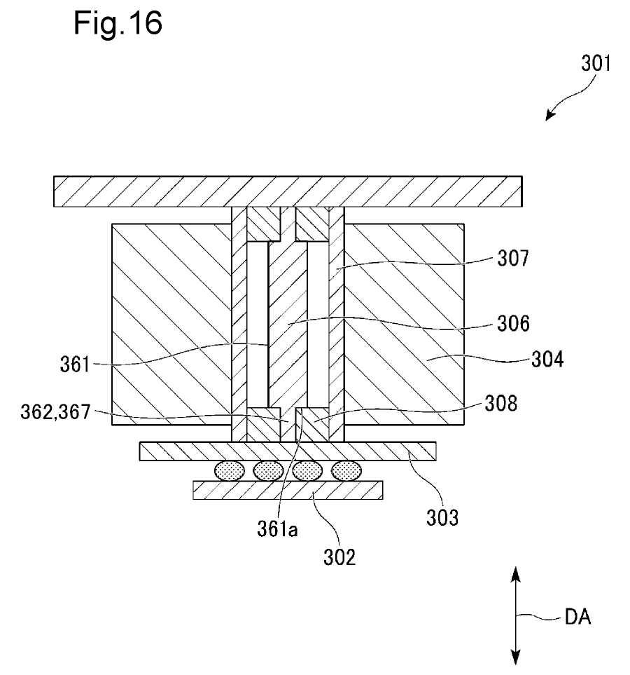

As illustrated in FIG. 16, a quantum device 301 of the present example embodiment includes a quantum chip 302, an interposer 303, and a socket 304.

The quantum chip 302 is mounted on the interposer 303.

The socket 304 includes a first movable pin 306, an outer conductor 307, and a first dielectric member 308.

The first movable pin 306 includes a first barrel 361 and a first plunger 362.

The first barrel 361 has a first end 361a in a first direction of an axial direction DA.

The first plunger 362 is movable in the axial direction DA with respect to the first barrel 361.

The outer conductor 307 is located at the outer periphery of the first plunger 362 with the first dielectric member 308 interposed between the outer conductor 307 and the first plunger 362, and is in contact with the interposer 303.

The first plunger 362 has a first distal portion 367 that protrudes from the first end 361a in the axial direction DA and is in contact with the interposer 303.

The first dielectric member 308 covers the outer periphery of the first distal portion 367 from the first end 361a to the interposer 303.

### Operation and Effect

According to the quantum device 301 of the present example embodiment, the first dielectric member 308 covers the outer periphery of the first distal portion 367 from the first end 361a (of the first barrel 361) to the interposer 303.

With this configuration, the characteristic impedance from the first end 361a to the portion where the first distal portion 367 is in contact with the interposer 303 can be adjusted by the first dielectric member 308.

As a result, the characteristic impedance of the connection portion of the interposer 303 and the socket 304 can be matched.

Therefore, the electrical characteristics of the connection portion can be improved.

While the present disclosure has been particularly shown and described with reference to example embodiments thereof, the present disclosure is not limited to these example embodiments. It will be understood by those of ordinary skill in the art that various changes in form and details may be made therein without departing from the present disclosure as defined by the claims. And each example embodiment can be appropriately combined with other example embodiments.

Some or all of the above-described example embodiments may be described as the following Supplementary Notes, but are not limited to the following Supplementary Notes.

### Supplementary Note 1

A quantum device including

a quantum chip,

an interposer on which the quantum chip is mounted, and

a socket including a first movable pin including a first barrel having a first end in a first direction of an axial direction and a first plunger movable in the axial direction with respect to the first barrel, a first dielectric member, and an outer conductor located at an outer periphery of the first plunger with the first dielectric member interposed between the outer conductor and the first plunger and in contact with the interposer, wherein

the first plunger has a first distal portion that protrudes in the axial direction from the first end and is in contact with the interposer, and

the first dielectric member covers an outer periphery of the first distal portion from the first end to the interposer.

### Supplementary Note 2

The quantum device according to Supplementary Note 1, further including a printed circuit board located further in a second direction of the axial direction than the socket, wherein

the first barrel has a second end in a second direction of the axial direction, the second direction being opposite to the first direction,

the first movable pin includes a second plunger movable in the axial direction with respect to the first barrel,

the second plunger has a second distal portion protruding from the second end in the axial direction and in contact with the printed circuit board,

the outer conductor is in contact with the printed circuit board, and

the socket further includes a second dielectric member covering an outer periphery of the second distal portion from the second end to the printed circuit board.

### Supplementary Note 3

The quantum device according to Supplementary Note 1 or 2, wherein

the first dielectric member has a thickness equal to a distance between the first end and the interposer in the axial direction.

### Supplementary Note 4

The quantum device according to any one of Supplementary Notes 1 to 3, wherein

the socket has a cylindrical coaxial structure with the first movable pin as a central conductor.

### Supplementary Note 5

The quantum device according to any one of Supplementary Notes 1 to 3, wherein

the socket has a cylindrical coaxial structure with the first movable pin as a central conductor, and

the outer conductor has a plane in contact with the interposer in the first direction of the axial direction.

### Supplementary Note 6

The quantum device according to any one of Supplementary Notes 1 to 3, wherein

the socket has a cylindrical coaxial structure with the first movable pin as a central conductor, and

the outer conductor has a protrusion in contact with the interposer in the first direction of the axial direction.

### Supplementary Note 7

The quantum device according to Supplementary Note 2, wherein

the socket has a cylindrical coaxial structure with the first movable pin as a central conductor, and

the outer conductor has a plane in contact with the printed circuit board in the second direction of the axial direction.

### Supplementary Note 8

The quantum device according to Supplementary Note 2, wherein

the socket has a cylindrical coaxial structure with the first movable pin as a central conductor, and

the outer conductor has a protrusion in contact with the printed circuit board in the second direction of the axial direction.

### Supplementary Note 9

The quantum device according to Supplementary Note 1 or 2, wherein

the outer conductor includes a plurality of second movable pins surrounding the first movable pin.

### Supplementary Note 10

The quantum device according to Supplementary Note 9, wherein

the plurality of second movable pins is disposed on a circumference centered on the first movable pin.

The previous description of embodiments is provided to enable a person skilled in the art to make and use the present disclosure. Moreover, various modifications to these example embodiments will be readily apparent to those skilled in the art, and the generic principles and specific examples defined herein may be applied to other embodiments without the use of inventive faculty. Therefore, the present disclosure is not intended to be limited to the example embodiments described herein but is to be accorded the widest scope as defined by the limitations of the claims and equivalents.

Further, it is noted that the inventor's intent is to retain all equivalents of the claimed invention even if the claims are amended during prosecution.

1. A quantum device comprising:
a quantum chip;
an interposer on which the quantum chip is mounted; and
a socket including a first movable pin including a first barrel having a first end in a first direction of an axial direction and a first plunger movable in the axial direction with respect to the first barrel, a first dielectric member, and an outer conductor located at an outer periphery of the first plunger with the first dielectric member interposed between the outer conductor and the first plunger and in contact with the interposer, wherein
the first plunger has a first distal portion that protrudes in the axial direction from the first end and is in contact with the interposer, and
the first dielectric member covers an outer periphery of the first distal portion from the first end to the interposer.

2. The quantum device according to claim 1, further comprising a printed circuit board located further in a second direction of the axial direction than the socket, wherein
the first barrel has a second end in a second direction of the axial direction, the second direction being opposite to the first direction,
the first movable pin includes a second plunger movable in the axial direction with respect to the first barrel,
the second plunger has a second distal portion protruding from the second end in the axial direction and in contact with the printed circuit board,
the outer conductor is in contact with the printed circuit board, and
the socket further includes a second dielectric member covering an outer periphery of the second distal portion from the second end to the printed circuit board.

3. The quantum device according to claim 1, wherein
the first dielectric member has a thickness equal to a distance between the first end and the interposer in the axial direction.

4. The quantum device according to claim 1, wherein
the socket has a cylindrical coaxial structure with the first movable pin as a central conductor.

5. The quantum device according to claim 1, wherein
the socket has a cylindrical coaxial structure with the first movable pin as a central conductor, and
the outer conductor has a plane in contact with the interposer in the first direction of the axial direction.

6. The quantum device according to claim 1, wherein
the socket has a cylindrical coaxial structure with the first movable pin as a central conductor, and
the outer conductor has a protrusion in contact with the interposer in the first direction of the axial direction.

7. The quantum device according to claim 2, wherein
the socket has a cylindrical coaxial structure with the first movable pin as a central conductor, and
the outer conductor has a plane in contact with the printed circuit board in the second direction of the axial direction.

8. The quantum device according to claim 2, wherein
the socket has a cylindrical coaxial structure with the first movable pin as a central conductor, and
the outer conductor has a protrusion in contact with the printed circuit board in the second direction of the axial direction.

9. The quantum device according to claim 1, wherein
the outer conductor includes a plurality of second movable pins surrounding the first movable pin.

10. The quantum device according to claim 9, wherein
the plurality of second movable pins is disposed on a circumference centered on the first movable pin.
